(19) United States
(12) Patent Application Publication
(10) Pub. No.: US 2006/0125504 A1
(43) Pub. Date: Jun. 15, 2006

(54) Printed circuit board for burn-in testing

(75) Inventors: Kok Tong Tan, Singapore (SG); Wan Mei Yvonne Lee, Singapore (SG)

Correspondence Address: ROTHWELL, FIGG, ERNST & MANBECK, P.C., 1425 K STREET, N.W., SUITE 800, WASHINGTON, DC, 20005, US

(73) Assignee: SYSTEMS ON SILICON MANUFACTURING COMPANY PTE. LTD., Singapore (SG)

(21) Appl. No.: 11/008,569

(22) Filed: Dec. 10, 2004

(51) Int. Cl. G01R 31/26

(52) U.S. Cl. 324/765

(57) ABSTRACT

A burn-in PCB comprising an adapter socket for receiving at least one program card; a plurality of test sockets for receiving test components; wherein one or more of the test sockets are electrically connected to the adapter socket by way of the printed circuit of the burn-in PCB; and wherein electrical connections for burn-in testing to respective test components received in said one or more test sockets on the burn-in PCB are at least in part formed by the printed circuit on said at least one program card received in the adapter socket.

### FIELD OF INVENTION

The present invention relates broadly to a burn-in printed circuit board (PCB), to an assembly of printed circuit boards (PCBs) for burn-in testing, and to a method of performing burn-in testing.

### BACKGROUND

In the manufacturing of electronic devices, a High Temperature Operation Life (HTOL) Test is typically performed for the purpose of qualification or monitoring to screen or eliminate marginal devices. These marginal devices are those with inherent defects or defects resulting from manufacturing aberrations which cause time and stress dependent failures. The HTOL test is conducted at accelerated operating conditions that stress the microcircuits which will reveal time and stress dependent failure modes.

The HTOL test is typically conducted in a high temperature oven and the Devices Under Test are typically DC biased via a Burn-In board. The Burn-In board layout (or blue print) is built according to the test chip requirements. Therefore, for each technology, a set of Burn-In boards has to be built to support the required burn-in test.

Furthermore, for typical monitoring of processes, the burn-in boards are process specific. Thus, a copy of the blue print of each specific burn-in board is required to build these boards.

Limitations of such a practice of building burn-in boards for process or test chip specific requirements include cost, where for each process, a minimum of about 20 boards are typically needed. The cost for such boards can be significant (eg. for semiconductor chip packages such as the Quad Flat Package 100L or QFP100L). Furthermore, due to specific burn-in boards being built and being in large numbers, long maintenance hours such as yearly maintenance sessions are required for these boards. Similarly, due to the large number of burn-in boards built, the storage space required for them is significant as well.

Hence, it is with the knowledge of the above concerns and restrictions that the present invention has been made and is now reduced to practice.

### SUMMARY

In accordance with a first aspect of the present invention there is provided an assembly of printed circuit boards (PCBs) for burn-in testing comprising one or more program PCBs; at least one burn-in PCB comprising an adapter socket for receiving at least one of the program PCBs; a plurality of test sockets for receiving test components; wherein one or more of the test sockets are electrically connected to the adapter socket by way of the printed circuit of the burn-in PCB; and wherein electrical connections for burn-in testing to respective test components received in said one or more test sockets on the burn-in PCB are at least in part formed by the printed circuit on said at least one program PCB received in the adapter socket.

The printed circuits on the respective program PCBs may comprise one or more passive components.

The test sockets may comprise different sockets for different types of test components.

The test components may comprise one or more IC chips.

The printed circuit of the burn-in PCB may comprise a first layout component for common routing from a connector of the burn-in PCB to each of the test sockets, and a second layout component for connections between each test socket and the adapter socket.

In accordance with a second aspect of the present invention there is provided a burn-in PCB comprising an adapter socket for receiving at least one program card; a plurality of test sockets for receiving test components; wherein one or more of the test sockets are electrically connected to the adapter socket by way of the printed circuit of the burn-in PCB; and wherein electrical connections for burn-in testing to respective test components received in said one or more test sockets on the burn-in PCB are at least in part formed by the printed circuit on said at least one program card received in the adapter socket.

The test sockets may comprise different sockets for different types of test components.

The test components may comprise one or more IC chips.

The printed circuit of the burn-in PCB may comprise a first layout component for common routing from a connector of the burn-in PCB to each of the test sockets, and a second layout component for connections between each test socket and the adapter socket.

In accordance with a third aspect of the present invention there is provided method of performing burn-in testing, the method comprising providing one or more program PCBs; providing at least one burn-in PCB comprising an adapter socket for receiving at least one of the program PCBs; a plurality of test sockets for receiving test components; wherein one or more of the test sockets are electrically connected to the adapter socket by way of the printed circuit of the burn-in PCB; and forming electrical connections for burn-in testing to the test components received in said one or more test sockets on the burn-in PCB at least in part by utilising the printed circuit on said at least oneprogram PCB received in the adapter socket.

The method may further comprise utilising one or more passive components on the respective program cards to form the electrical connections to the test components.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 is schematic diagram of a burn-in board and two program cards in an example embodiment.

FIGS. 2A) to C) show pictures of a program card, a detail of a burn-in board, and the burn-in board respectively in an example embodiment.

FIG. 3 is a flowchart illustrating a method of performing burn-in testing in an example embodiment.

### DETAILED DESCRIPTION

In an example embodiment, a burn-in board is constructed where this burn-in board may be used for different requirements of test chips and processes. In this example embodiment, the burn-in board constructed consists of a burn-in board portion that has been designed for general purpose use as well as an adapter that allows for receipt of a custom-made program card that is built for specific requirements of test chips and processes.

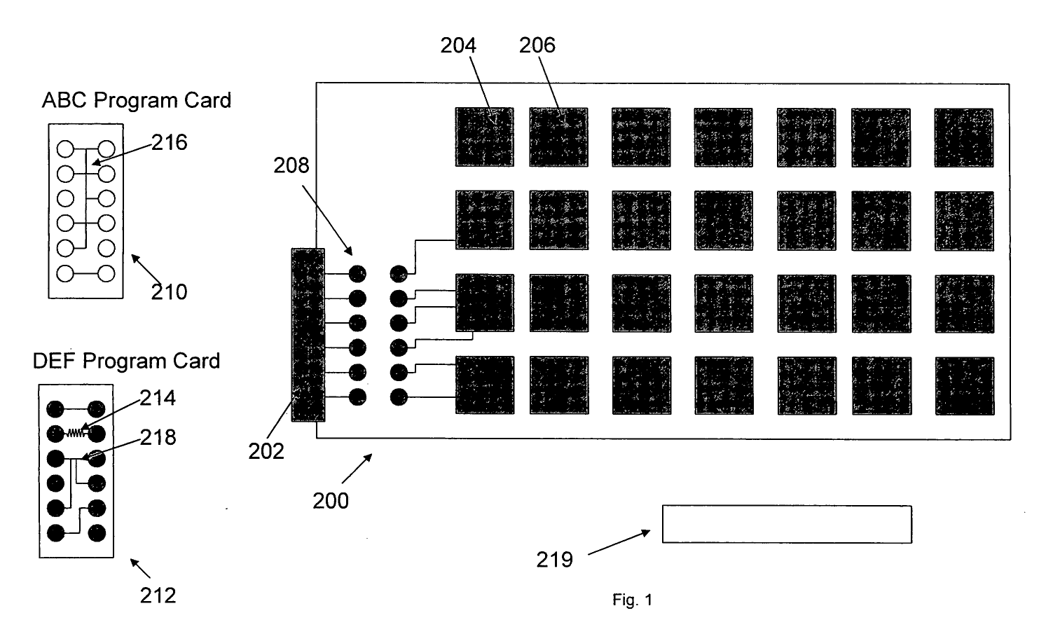

In the example embodiment, with reference to FIG. 1, a burn-in board 200 is described. A general layout for common routing from an edge connector 202 to each test socket, eg. 204 and 206, is drawn and routed. This general layout may then be adapted for use for various different requirements of test chips and processes. The specific circuit connections that are required for each specific application of the burn-in board are re-routed to an adapter socket 208. In this way, the role of performing different specific circuitry tasks is handled by different program cards, eg. 210 and 212, which are interchangeable on the burn-in board 200 by utilising the adapter socket 208. These different specific circuitry tasks may be for different specific test chip or process requirements.

Each program card, eg. 210 and 212, allows passive components such as capacitors or resistors, eg. 214, to be mounted or added. Therefore, custom modifications to circuits, eg. 216 and 218, may be made easily on each low cost program card, eg. 210 and 212. These custom circuits, eg. 216 and 218 may be produced for different applications including for experimental purposes.

In this example embodiment, the program cards 210 and 212 represent circuitry for different specific processes ABC and DEF respectively. To use the burn-in board 200 for process ABC, a program card 210 routed with an application-specific circuitry 216 is inserted into an adapter 208 socket. The burn-in sockets, eg. 204 and 206, are then inserted with chips for process ABC. The edge connector 202 may then be used to connect to the DC bias interface of a high temperature oven (not shown), to stress test chips for process ABC. In another usage of the burn-in board 200 in this example embodiment such as for process DEF, the program card 210 is replaced with a program card 212 containing application-specific circuitry 218. It is noted that no further modifications need to be carried out on the burn-in board 200 for a different test.

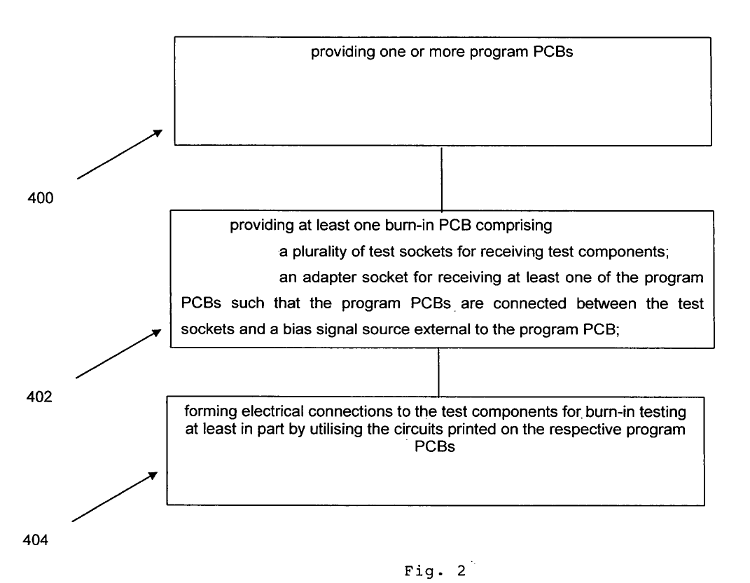

With reference to FIGS. 2A) to C), it is illustrated that a program card 302 can be inserted and is interchangeable in an adapter socket 304. In this example embodiment, multiple adapter sockets, eg. 310, are provided for flexibility of implementation in different applications.

In this example embodiment, by building program cards, eg. 302, corresponding to different requirements for use on a general purpose-use burn-in board 306, the total cost of building a typical burn-in board is reduced. Thus, significant savings compared with building a new burn-in board for each purpose may be achieved. Another advantage in this example embodiment is the prevention of waste as the burn-in board 306 need not be scrapped or discarded upon a test chip or process being terminated. The burn-in board 306 may instead be “recycled” for existing processes or test chips.

In addition, with the usage of program cards, eg. 302, in the example embodiment, instead of constructing burn-in boards for each application, storage requirements and maintenance hours are lower than if different burn-in boards are built for each different purpose. An estimation of maintenance hours for the burn-in board 306 in this example embodiment may be about 2 hours.

Moreover, the flexibility to adapt or “switch” the burn-in boards, eg. 306, by insertion of different application-specific program cards, eg. 302, provides an ability to have, if required, a large number of burn-in boards, eg. 306, to support ad-hoc evaluations for a specific process or test chip. This may be useful as such evaluations may typically require a large number of burn-in boards and in this example embodiment, these burn-in boards, eg. 306, need not be built but rather, they may be simply “switched” from other applications or test chips by inserting the required application-specific program cards, eg. 302, into the adapter socket e.g. 304, 310, of the burn-in boards, eg. 306. Furthermore, for experimental purposes, a program card, eg. 302, may be simply hand-built for use for a new test chip. This is useful in reducing lead-time as well as saving costs in constructing a burn-in board for this purpose.

Further to the above, in this example embodiment, usage of the burn-in board 306 and program cards, eg. 302, allows an integration of several passive components such as resistors or capacitors, in addition to allowing mass re-routing. The use of the program cards, eg. 302, may prevent the possibility of incidental wrong configurations for the burn-in board 306, as the routing is printed permanently on the program card e.g. 302. This can provide an advantage over e.g. the usage of typical burn-in boards where jumpers may be used as shorting devices in changing the configurations. Cost savings may be especially useful and applicable to burn-in or testing vendors or providers as this example embodiment will potentially reduce their expandable cost for constructing burn-in boards directly.

FIG. 3 is a flowchart illustrating a method of performing burn-in testing in an example embodiment. The method comprises, at step 400, providing one or more program PCBs, and, at step 402, providing at least one burn-in PCB comprising an adapter socket for receiving at least one of the program PCBs; a plurality of test sockets for receiving test components; and wherein the test sockets are electrically connected to the adapter socket by way of the printed circuit of the burn-in PCB. At step 404, electrical connections to the test components are formed for burn-in testing at least in part by utilising the circuits printed on the respective program PCBs.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

1. An assembly of printed circuit boards (PCBs) for burn-in testing comprising:
one or more program PCBs;
at least one burn-in PCB comprising:
a plurality of test sockets for receiving test components;
an adapter socket for receiving at least one of the program PCBs such that the program PCBs are connected between the test sockets and a bias signal source external to the program PCB:
wherein one or more of the test sockets are electrically connected to the adapter socket by way of the printed circuit of the burn-in PCB; and
wherein electrical connections between the bias signal source and said one or more test sockets on the burn-in PCB include the printed circuit on said at least one program PCB received in the adapter socket.

2. The assembly as claimed in claim 1, wherein the printed circuits on the respective program PCBs comprise one or more passive components.

3. The assembly as claimed in claim 1, wherein the test sockets comprise different sockets for different types of test components.

4. The assembly as claimed in claim 1, wherein test components comprise one or more IC chips.

5. The assembly as claimed in claim 1, wherein the printed circuit of the burn-in PCB comprises a first layout component for common routing from a connector of the burn-in PCB to each of the test sockets, and a second layout component for connections between each test socket and the adapter socket.

6. A burn-in PCB comprising:
a plurality of test sockets for receiving test components;
an adapter socket for receiving at least one program PCB such that the program PCBs are connected between the test sockets and a bias signal source external to the program PCB:
wherein one or more of the test sockets are electrically connected to the adapter socket by way of the printed circuit of the burn-in PCB; and
wherein electrical connections between the bias signal source and said one or more test sockets on the burn-in PCB include the printed circuit on said at least one program PCBs received in the adapter socket.

7. The PCB as claimed in claim 6, wherein the test sockets comprise different sockets for different types of test components.

8. The PCB as claimed in claim 6, wherein the test components comprise one or more IC chips.

9. The PCB as claimed in claim 6, wherein the printed circuit of the burn-in PCB comprises a first layout component for common routing from a connector of the burn-in PCB to each of the test sockets, and a second layout component for connections between each test socket and the adapter socket.

10. A method of performing burn-in testing, the method comprising:
providing one or more program PCBs;
providing at least one burn-in PCB comprising
a plurality of test sockets for receiving test components;
an adapter socket for receiving at least one of the program PCBs such that the program PCBs are connected between the test sockets and a bias signal source external to the program PCB;
wherein one or more of the test sockets are electrically connected to the adapter socket by way of the printed circuit of the burn-in PCB; and
wherein electrical connections between the bias signal source and said one or more test sockets on the burn-in PCB include the printed circuit on said at least one program PCB received in the adapter socket.

11. The method as claimed in claim 10, further comprising utilising one or more passive components on the respective program cards to form the electrical connections to the test components.
